(19) United States
(12) Patent Application Publication
(10) Pub. No.: US 2011/0108999 A1
(43) Pub. Date: May 12, 2011

(54) Microelectronic package and method of manufacturing same

(76) Inventors: Ravi K. Nalla, Chandler, AZ (US); Juan A. Maez, Chandler, AZ (US); Mathew J. Manusharow, Phoenix, AZ (US)

(21) Appl. No.: 12/590,350

(22) Filed: Nov. 6, 2009

(51) Int. Cl. H01L 23/488; H01L 21/60

(52) U.S. Cl. 257/784; 438/127; 257/E23.023; 257/E21.509

(57) ABSTRACT

A microelectronic package comprises a die (210) having attached thereto a first plurality of electrically conductive pads (211). The microelectronic package further comprises a first layer (220) and a second layer (130). The first layer has a first plurality of electrically conductive vias (121) electrically connected to one of the first plurality of electrically conductive pads. The second layer comprises a second plurality of electrically conductive pads (131) located around a perimeter (135) of the second layer and a plurality of electrically conductive traces (132) electrically connected to one of the first plurality of electrically conductive vias and to one of the second plurality of electrically conductive pads. The microelectronic package also comprises a plurality of wirebonds (240), each one of which is electrically connected to one of the second plurality of electrically conductive pads.

### FIELD OF THE INVENTION

The disclosed embodiments of the invention relate generally to microelectronic devices, and relate more particularly to packaging methods and designs for such devices.

### BACKGROUND OF THE INVENTION

Computer microprocessors, chipsets, and other microelectronic devices are often placed within a microelectronic package in order to provide protection against damage, connectivity with other components in a computer system, and other advantages. Stacked microelectronic packages are common-place today for applications in several market segments such as smartphones. Within a stacked (or other) package, the die to substrate connection is traditionally made either with wire-bonding or with controlled collapse chip connect (C4) bumping.

### BRIEF DESCRIPTION OF THE DRAWINGS

The disclosed embodiments will be better understood from a reading of the following detailed description, taken in conjunction with the accompanying figures in the drawings in which:

FIG. 1 is a plan view of a microelectronic package according to an embodiment of the invention;

FIG. 2 is a cross-sectional view of the microelectronic package of FIG. 1 according to an embodiment of the invention;

FIG. 3 is a flowchart illustrating a method of manufacturing a microelectronic package according to an embodiment of the invention;

FIGS. 4-9 are cross-sectional views of the microelectronic package of FIGS. 1 and 2 at various particular points in its manufacturing process according to an embodiment of the invention;

FIG. 10 depicts a stacked die package according to an embodiment of the invention;

FIG. 11 depicts a microelectronic package comprising stacked dies on a BBUL package solder attached to an underlying package with a POP configuration according to an embodiment of the invention; and

FIG. 12 depicts a microelectronic package comprising stacked dies on a BBUL package solder attached to an underlying package with a PIP configuration according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements, while similar reference numerals may, but do not necessarily, denote similar elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a microelectronic package comprises a die having attached thereto a first plurality of electrically conductive pads. These pads have a pitch no greater than 100 micrometers. The microelectronic package further comprises a first layer and a second layer located over the first layer. The first layer has a first plurality of electrically conductive vias therein, each one of which is electrically connected to one of the first plurality of electrically conductive pads. The second layer comprises a second plurality of electrically conductive pads located around a perimeter of the second layer and further comprises a plurality of electrically conductive traces, each one of which is electrically connected to one of the first plurality of electrically conductive vias and to one of the second plurality of electrically conductive pads. The microelectronic package also comprises a plurality of wirebonds, each one of which is electrically connected to one of the second plurality of electrically conductive pads.

Stacked packages were mentioned above as being common in several market segments. Such packages will likely become even more widely used in the future as computer systems continue along the path toward greater computing power and smaller size. Yet the interconnect technology that will be used in these smaller packages is an issue that must be addressed. While wire-bonding is a very well-established technology, one of its key disadvantages is that it often leads to an increase in die size owing to the need to arrange the pads around the periphery of the die and to the fact that the number of rows of pads that can be wire-bonded to is limited. This disadvantage is often addressed by using C4 technology instead, because C4 technology is characterized by an ability to produce a higher number of bonds (e.g., distributed in all array pattern). However, C4 technology is also facing pitch scaling limitations owing to bumping and assembly process limitations.

Embodiments of the invention address these issues by using the so-called Bumpless Build-up Layer (BBUL) technology to create a package enveloping the die. The pitch dimensions within the die are scaled down to allow for a decrease in the die size. The BBUL technology is then used to “distribute” the die bumps into peripheral rows of pads on the package. These pads can then be wire-bonded to other packages, or to other silicon die, as needed to form a stacked package. For example, embodiments of the invention enable the use of very fine pitch die in stacked packages. If desired, some of these pads can be used to enable Package on Package (POP) and Package in Package (PIP) architectures.

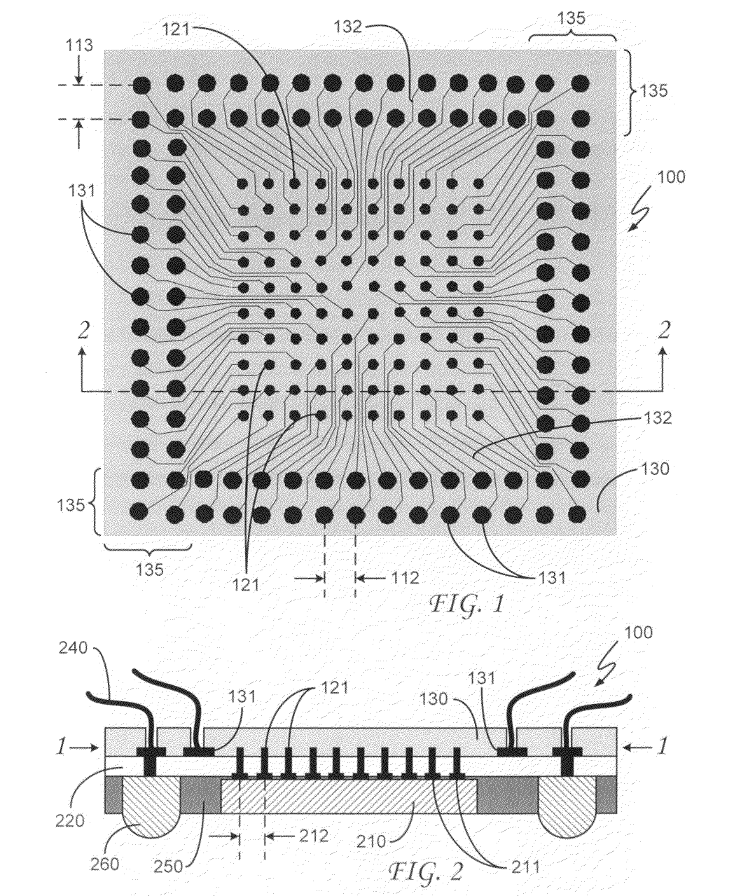

Referring now to the drawings, FIG. 1 is a plan view and FIG. 2 is a cross-sectional view of a microelectronic package 100 according to an embodiment of the invention. FIG. 2 is taken along a line 2-2 of FIG. 1, while FIG. 1 illustrates a layer of FIG. 2 that is indicated by arrows 1-1. The wirebonds (introduced and described below) shown in FIG. 2 are omitted from FIG. 1 in order to enhance the clarity of the figure. Similarly, and for the same reason, the electrically conductive traces (introduced and described below) that are shown in FIG. 1 are omitted from FIG. 2.

As illustrated in FIGS. 1 and 2, microelectronic package 100 comprises a die 210 having attached thereto a plurality of electrically conductive pads 211 having a pitch 212 not exceeding 100 micrometers (also referred to herein as “microns” or “μm”). (At larger pitches, existing technologies are more likely to be sufficient.) In the illustrated embodiment, die 210 is at least partially encapsulated in a mold compound 250. Among other reasons, this is done in order to provide a base upon which to build the rest of the package and also to help with warpage control, thermal dissipation, mechanical strengthening, etc. Additionally, in the illustrated embodiment microelectronic package 100 is a bumpless build-up layer (BBUL) package. BBUL technology eliminates the die attach process and therefore has the advantage of, among other things, avoiding the problem of substrate warpage and of developing an assembly process at very fine C4 pitches.

A layer 220 of microelectronic package 100 contains a plurality of electrically conductive vias 121, each one of which is electrically connected to one of electrically conductive pads 211. In the illustrated embodiment, electrically conductive vias 121 are arranged in a 10×10 array at layer 220. Layer 220 may be composed of a suitable wafer dielectric material.

Microelectronic package 100 further comprises a layer 130 located over layer 220 and having formed therein a plurality of electrically conductive pads 131 located around a perimeter 135 of layer 130 and further having formed therein a plurality of electrically conductive traces 132, each one of which is electrically connected to one of electrically conductive vias 121 and to one of electrically conductive pads 131. Layer 130 may be composed of a photo-resist material such as solder resist, dry film resist, or the like. Still further, microelectronic package 100 comprises a plurality of wirebonds 240, each one of which is electrically connected to one of electrically conductive pads 131.

Traces 132, although shown as being confined to a single layer (layer 130), may in other embodiments be located in multiple layers. In other words, it is feasible that multiple layers can be used to route the traces running from vias 121 to pads 131 (i.e., C4 to outer pad). More specifically, a layer stack made up of layers similar to those shown can be used in order to route traces from the C4 area out to the larger pitch pads (such as pads 131). Vias can be added directly on vias 121, which would then run through layer 130, where a second layer of routing can be patterned. As an example, this routing could be patterned directly on layer 130. Once patterning is done, another resist would be patterned on top of this secondary routing layer. This process can be repeated for as many layers as necessary.

In the illustrated embodiment, perimeter 135 of layer 130 is made up of a portion of layer 130 that is located exterior to a footprint of die 210 projected onto layer 130. In FIG. 1, that footprint is generally represented by a square formed by the 10×10 array of electrically conductive vias 121. In some embodiments, electrically conductive pads 131 are arranged in multiple concentric rings within perimeter 135. In the illustrated embodiment, two such rings are shown.

As shown in the figures, electrically conductive pads 131 have a pitch 112 that is greater than pitch 212 of electrically conductive pads 211. As an example, pitch 112 can be approximately 100 μm. The pattern is designed to distribute the L0 pads to a peripheral ring of L1 pads that will enable wire-bonding. Some of the L1 pads may be distributed at a larger pitch to enable POP (package-on-package) or PIP (package-in-package) capability. In that regard, the illustrated embodiment comprises a first group of electrically conductive pads 131 having pitch 112 and a second group (possibly at the corners of layer 130, as shown, but not necessarily located there) of electrically conductive pads 131 having a pitch 113 that is greater than pitch 112. Mold compound 250 may, in a POP or similar architecture, contain electrically conductive vias therein that will receive POP solder bumping or the like. In FIG. 2 these electrically conductive vias are filled with POP solder bumps 260 and thus are not visible.

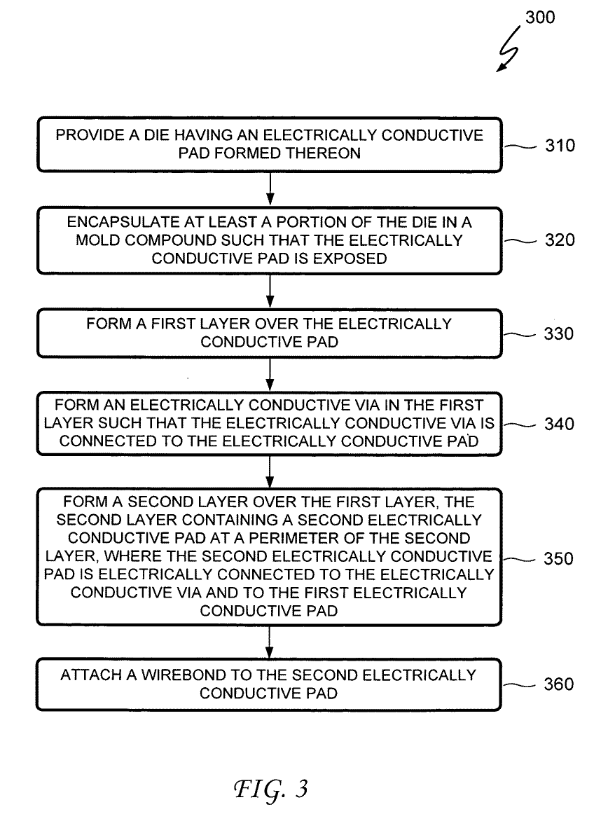

FIG. 3 is a flowchart illustrating a method 300 of manufacturing a microelectronic package according to an embodiment of the invention. As an example, method 300 may result in the formation of a microelectronic package that is similar to microelectronic package 100 that is first shown in FIG. 1.

A step 310 of method 300 is to provide a die having an electrically conductive pad formed thereon. Only a single electrically conductive pad is mentioned here (and at various points in the following paragraphs) in order to simplify the discussion; it should be understood that the die could, and likely would, have multiple electrically conductive pads formed thereon, and that the single pad described is representative of all such pads. As an example, the die and the electrically conductive pad can be similar to, respectively, die 210 and electrically conductive pads 211 that are shown in FIG. 2.

In one embodiment, a previous step of method 300 comprises, or step 310 further comprises, dispensing a suitable adhesive on a mounting plate that will serve as a carrier for the “redistributed” BBUL wafer, after which singulated die are placed on the adhesive layer with the active side up. The die can have very small bumps (L0 pads) with very fine bump pitches 212. To take one example, the die might have a 15 μm bump diameter at a 25 μm pitch.

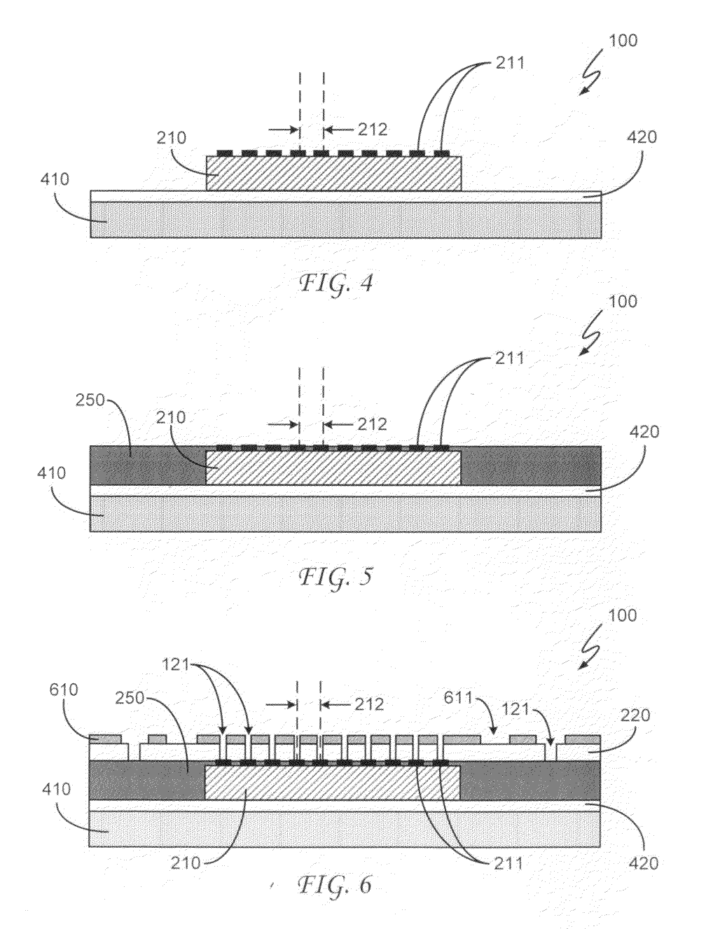

FIGS. 4-9 are cross-sectional views of microelectronic package 100 at various particular points in its manufacturing process according to an embodiment of the invention. As illustrated in FIG. 4, die 210 is mounted on a mounting plate 410 using an adhesive 420.

A step 320 of method 300 is to encapsulate at least a portion of the die in a mold compound such that the electrically conductive pad is exposed. As an example, the mold compound can be similar to mold compound 250 that is shown in FIG. 2. In one embodiment, step 320 (or another step) comprises grinding away or otherwise removing a portion of the mold compound (originally dispensed to completely cover the die and the pad) in order to expose the electrically conductive pad. FIG. 5 depicts mold compound 250 encapsulating die 210 but exposing electrically conductive pads 211.

A step 330 of method 300 is to dispense or otherwise form a first layer over the electrically conductive pad. Accordingly, in one embodiment step 330 comprises forming a dielectric layer. As an example, the first layer can be similar to layer 220 that is shown in FIG. 2.

A step 340 of method 300 is to form an electrically conductive via in the first layer such that the electrically conductive via is connected to the electrically conductive pad. As an example, the electrically conductive via can be similar to electrically conductive vias 121 that are shown in FIG. 1. These vias connect L0 and L1 with each other (and thus may be referred to as L0-L1 vias). FIG. 6 depicts layer 220 over mold compound 250, die 210, and electrically conductive pads 211, and further illustrates that electrically conductive vias 121 have been opened up in layer 220 on top of the L0 pads (i.e., electrically conductive pads 211). As mentioned above, layer 220 can be composed of a suitable wafer dielectric material. Electrically conductive vias 121 may, in one embodiment, have a 5 μm diameter with an alignment of plus or minus 5 μm.

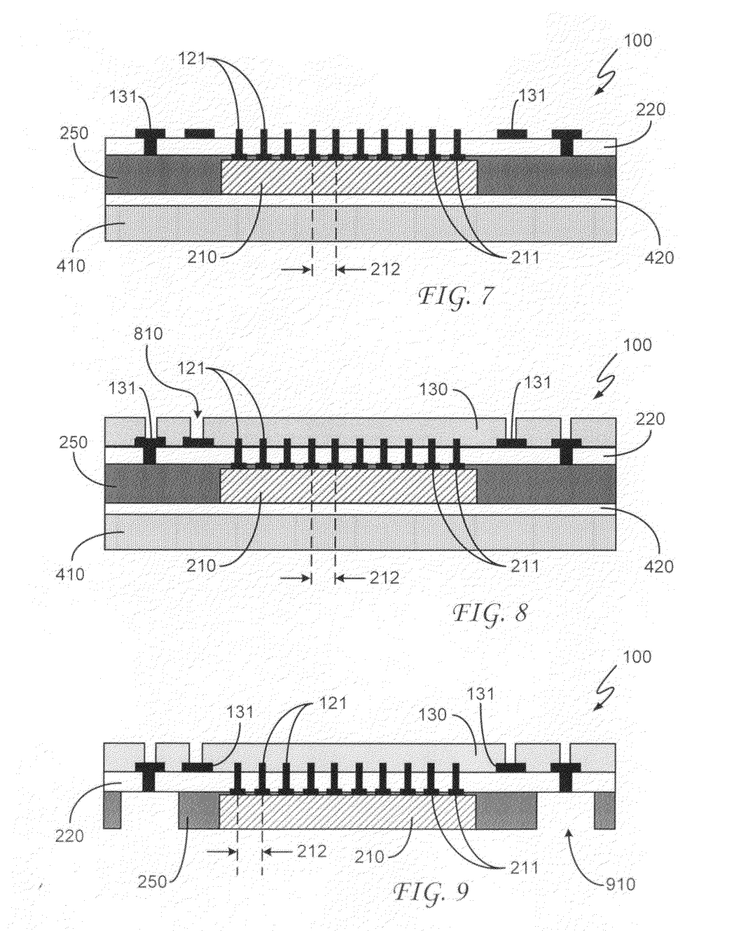

Also depicted in FIG. 6 is a dry film resist or other photo-resist material 610 that has been spun on (or otherwise applied) and patterned on top of the L0-L1 dielectric (i.e., layer 220). The pattern serves to open up the L0-L1 vias and the L1 pads on top of the vias (see FIG. 7) for routing on the L1 layer (i.e., layer 130). In an exemplary embodiment, the L1 routing (i.e., traces 132—see FIG. 1) may be formed at dimensions of 2/2 μm L/S (line/space). The pattern is designed to distribute the L0 pads to a peripheral ring of L1 pads that will enable wire-bonding, as described above. An opening 611 in photo-resist material 610 will subsequently receive one of the L1 pads. As has also been described, some of the L1 pads may be distributed at a larger pitch to enable POP capability. FIG. 7 depicts a point in the manufacturing process at which copper (or other electrically conductive) plating has been deposited or otherwise applied in order to form the patterns described above. Electrically conductive pads 131 (i.e., the L1 pads) are thus visible on top of layer 220. Photo-resist material 610 has been removed using any suitable process.

A step 350 of method 300 is to form a second layer over the first layer, the second layer containing a second electrically conductive pad at a perimeter of the second layer, where the second electrically conductive pad is electrically connected to the electrically conductive via and to the first electrically conductive pad. As an example, the second layer can be similar to layer 130 that is first shown in FIG. 1. Accordingly, in one embodiment step 350 comprises forming a photo-resist layer. As another example, the perimeter of the second layer can be similar to perimeter 135, also shown in FIG. 1. Accordingly, in one embodiment the perimeter of the second layer is made up of a portion of the second layer located exterior to a footprint of the die projected onto the second layer.

In a particular embodiment, the second electrically conductive pad is one of a plurality of electrically conductive pads, and step 350 comprises arranging the second plurality of electrically conductive pads in multiple concentric rings within the perimeter of the second layer. In the same or another embodiment, step 350 comprises arranging the second plurality of electrically conductive pads such that they have a second pitch that is greater than the first pitch. In some embodiments, step 350 comprises arranging the second plurality of electrically conductive pads into a first group having the second pitch and a second group having a third pitch that is greater than the second pitch.

FIG. 8 depicts layer 130 (composed, for example, of solder resist, dry film resist, or the like) that has been dispensed and patterned to form openings 810 for the wirebonds that are formed in a subsequent step. If the BBUL package needs to be part of a POP package, vias are laser drilled through (or otherwise formed in) the mold compound in order to expose the L1 POP pads. FIG. 9 depicts microelectronic package 100 after the removal (using any suitable process) of mounting plate 410 and adhesive 420 and after the formation of vias 910 in mold compound 250. Any surface finish that may be needed for the wirebonds and POP pads may then be plated on or otherwise formed.

A step 360 of method 300 is to attach a wirebond to the second electrically conductive pad. As an example, the wirebond can be similar to wirebond 240 that is shown in FIG. 2. Step 360 or another step may include solder bumping for POP packaging, if desired. Following the performance of step 360, microelectronic package 100 may appear as depicted in FIGS. 1 and 2.

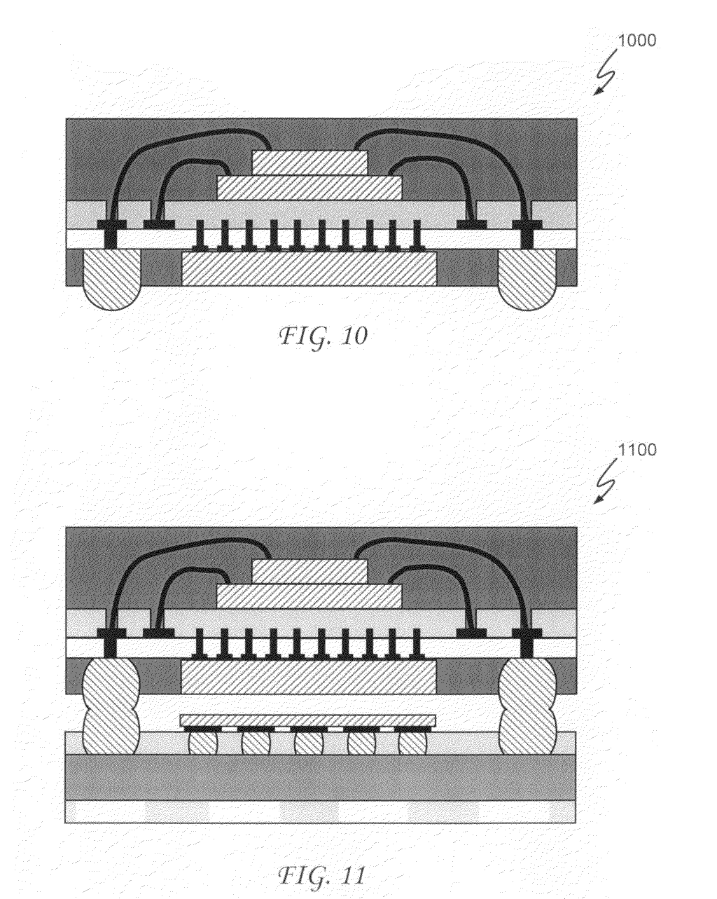

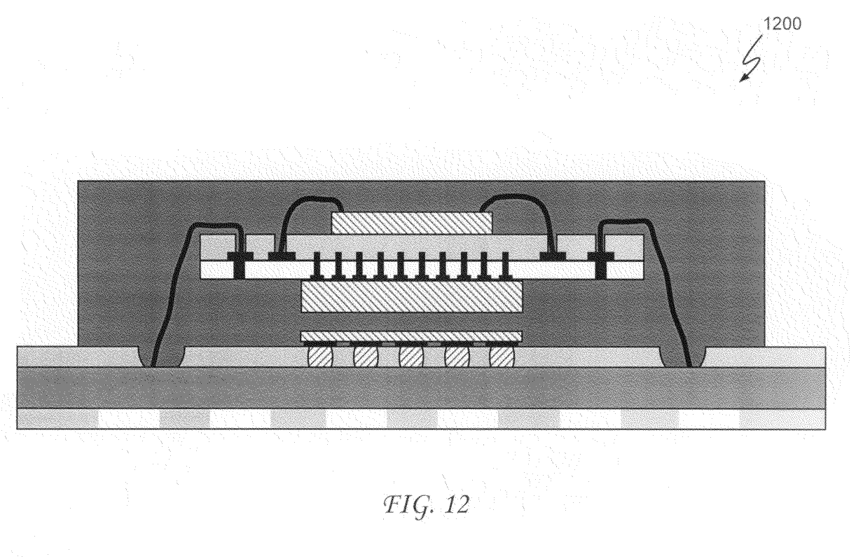

Other manifestations or embodiments of the invention in addition to those described above, including, for example, die placement with active side down, stacked die, PIP, and other package architectures, may also be created; some of these are shown in FIGS. 10-12. FIG. 10 depicts a stacked die package 1000 according to an embodiment of the invention. FIG. 11 depicts a microelectronic package 1100 comprising stacked dies on a BBUL package solder attached to an underlying package with a POP configuration according to an embodiment of the invention. FIG. 12 depicts a microelectronic package 1200 comprising stacked dies on a BBUL package solder attached to an underlying package with a PIP configuration according to an embodiment of the invention.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic package and the related structures and methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A microelectronic package comprising:
a die having attached thereto a first plurality of electrically conductive pads having a first pitch not exceeding 100 micrometers;
a first layer having formed therein a first plurality of electrically conductive vias, each one of which is electrically connected to one of the first plurality of electrically conductive pads;
a second layer located over the first layer and having formed therein a second plurality of electrically conductive pads located around a perimeter of the second layer and further having formed therein a plurality of electrically conductive traces, each one of which is electrically connected to one of the first plurality of electrically conductive vias and to one of the second plurality of electrically conductive pads; and
a plurality of wirebonds, each one of which is electrically connected to one of the second plurality of electrically conductive pads.

2. The microelectronic package of claim 1 wherein:
the perimeter of the second layer is made up of a portion of the second layer located exterior to a footprint of the die projected onto the second layer.

3. The microelectronic package of claim 2 wherein:
the second plurality of electrically conductive pads are arranged in multiple concentric rings.

4. The microelectronic package of claim 1 wherein:
the first layer is composed of a dielectric material.

5. The microelectronic package of claim 1 wherein:
the second layer is composed of a photo-resist material.

6. The microelectronic package of claim 1 wherein:
the second plurality of electrically conductive pads have a second pitch that is greater than the first pitch.

7. The microelectronic package of claim 6 wherein:
a first group of the second plurality of electrically conductive pads have the second pitch; and
a second group of the second plurality of electrically conductive pads have a third pitch that is greater than the second pitch.

8. The microelectronic package of claim 1 wherein:
the microelectronic package is a bumpless build-up layer package.

9. A bumpless build-up layer package comprising:
a die that is at least partially encapsulated in a mold compound and that has attached thereto a first plurality of electrically conductive pads having a first pitch not exceeding 100 micrometers;
a first layer having formed therein a first plurality of electrically conductive vias, each one of which is electrically connected to one of the first plurality of electrically conductive pads;
a second layer located over the first layer and having formed therein a second plurality of electrically conductive pads located around a perimeter of the second layer and further having formed therein a plurality of electrically conductive traces, each one of which is electrically connected to one of the first plurality of electrically conductive vias and to one of the second plurality of electrically conductive pads; and
a plurality of wirebonds, each one of which is electrically connected to one of the second plurality of electrically conductive pads.

10. The bumpless build-up layer package of claim 9 wherein:
the mold compound contains a second plurality of electrically conductive vias therein.

11. The bumpless build-up layer package of claim 9 wherein:
the perimeter of the second layer is made up of a portion of the second layer located exterior to a footprint of the die projected onto the second layer.

12. The bumpless build-up layer package of claim 11 wherein:
the second plurality of electrically conductive pads are arranged in multiple concentric rings.

13. The bumpless build-up layer package of claim 9 wherein:
the first layer is composed of a dielectric material; and
the second layer is composed of a photo-resist material.

14. The bumpless build-up layer package of claim 9 wherein:
the second plurality of electrically conductive pads have a second pitch that is greater than the first pitch.

15. The bumpless build-up layer package of claim 14 wherein:
a first group of the second plurality of electrically conductive pads have the second pitch; and
a second group of the second plurality of electrically conductive pads have a third pitch that is greater than the second pitch.

16. A method of manufacturing a microelectronic package, the method comprising:
providing a die having a first electrically conductive pad formed thereon;
encapsulating at least a portion of the die in a mold compound such that the first electrically conductive pad is exposed;
forming a first layer over the first electrically conductive pad;
forming an electrically conductive via in the first layer such that the electrically conductive via is connected to the first electrically conductive pad;
forming a second layer over the first layer, the second layer containing a second electrically conductive pad at a perimeter of the second layer, where the second electrically conductive pad is electrically connected to the electrically conductive via and to the first electrically conductive pad; and
attaching a wirebond to the second electrically conductive pad.

17. The method of claim 16 wherein:
forming the first layer comprises forming a dielectric layer; and
forming the second layer comprises forming a photo-resist layer.

18. The method of claim 16 wherein:
the perimeter of the second layer is made up of a portion of the second layer located exterior to a footprint of the die projected onto the second layer;
the first electrically conductive pad is one of a first plurality of electrically conductive pads;
the second electrically conductive pad is one of a second plurality of electrically conductive pads; and
forming the second layer comprises arranging the second plurality of electrically conductive pads in multiple concentric rings within the perimeter of the second layer.

19. The method of claim 18 wherein:
the first plurality of electrically conductive pads have a first pitch, and
forming the second layer comprises arranging the second plurality of electrically conductive pads such that they have a second pitch that is greater than the first pitch.

20. The method of claim 19 wherein:
forming the second layer comprises arranging the second plurality of electrically conductive pads into a first group having the second pitch and a second group having a third pitch that is greater than the second pitch.
